(19) United States
(12) Patent Application Publication
(10) Pub. No.: US 2021/0319746 A1
(43) Pub. Date: Oct. 14, 2021

(54) DISPLAY SCREEN AND DISPLAY DEVICE

(71) Applicant: SHENZHEN ROYOLE TECHNOLOGIES CO., LTD., Shenzhen (CN)

(72) Inventor: Weihua JIA, Shenzhen (CN)

(21) Appl. No.: 17/358,449

(22) Filed: Jun. 25, 2021

Related U.S. Application Data
(63) Continuation of application No. PCT/CN2018/124962, filed on Dec. 28, 2018.

(51) Int. Cl. G09G 3/3225; H01L 27/32

(52) U.S. Cl. CPC G09G 3/3225; G09G 2320/0233; H01L 27/326; H01L 27/3276

(57) ABSTRACT

The embodiments of the present disclosure disclose a display screen and a display device. A display screen (10) includes: a display panel (11), a compensation line assembly (12), a signal source circuit (13) and a compensation circuit (14). The display panel (11) includes a display area (111) and a non-display area (112). The compensation line assembly (12) is separately connected to each pixel unit. The signal source circuit (13) is configured to provide a preset driving voltage for each pixel unit. The compensation circuit (14) is configured to detect a real-time driving voltage of each pixel unit, determine a to-be-compensated pixel unit based on the preset driving voltage and the real-time driving voltage, and provide a compensation voltage for the to-be-compensated pixel unit. Therefore, brightness of the different display areas can be uniform, and brightness consistency of the display areas can be further improved.

### CROSS-REFERENCE TO RELATED APPLICATION

This application is a continuation of International Disclosure No. PCT/CN2018/124962, filed on Dec. 28, 2018. The disclosures of the aforementioned disclosures are hereby incorporated by reference in their entireties.

### TECHNICAL FIELD

The embodiments of the present disclosure relate to the field of display technologies, and in particular, to a display screen and a display device.

### BACKGROUND

During display by a display screen, a signal source transmits a driving voltage through a metal interconnection line to light up a display area to emit light. With the development of semiconductor processes and narrow bezel designs, metal interconnection lines have increasingly small widths but growing resistance. Consequently, pixel units in different display areas correspond to different driving voltages, resulting in a difference in brightness between the display areas.

### SUMMARY

The embodiments of the present disclosure provide a display screen and a display device, which can improve brightness consistency of display areas.

To solve the technical problem, the embodiments of the present disclosure provide the following technical solutions.

A display screen includes:

a display panel, including a display area and a non-display area, where the display area includes several pixel units;

a compensation line assembly, disposed in the non-display area, where the compensation line assembly is separately connected to each of the pixel units;

a signal source circuit, disposed on one side of the display panel and configured to provide a preset driving voltage for each of the pixel units; and

a compensation circuit, connected to the compensation line assembly and configured to detect a real-time driving voltage of each of the pixel units, determine a to-be-compensated pixel unit based on the preset driving voltage and the real-time driving voltage, and provide a compensation voltage for the to-be-compensated pixel unit.

Optionally, the compensation line assembly includes: several first compensation lines, disposed on one side of the non-display area, where one end of each of the first compensation lines is connected to a corresponding pixel unit, and the other end of each of the first compensation lines is connected to the compensation circuit.

Optionally, the display area includes a first display area and a second display area, the first display area and the second display area are symmetrical, and one end of each of the first compensation lines is connected to a corresponding pixel unit in the first display area.

The compensation line assembly further includes several second compensation lines, each of the second compensation lines is disposed on the other side of the non-display area, one end of each of the second compensation lines is connected to a corresponding pixel unit in the second display area, the other end of each of the second compensation lines is connected to the compensation circuit, and first compensation lines and second compensation lines that are connected to the same row of pixel units are symmetrical about a central axis of the display area.

Optionally, several first power lines and several second power lines are disposed in the display area, any two adjacent first power lines are parallel, any two adjacent second power lines are parallel, any one of the first power lines is perpendicular to any one of the second power lines, one end of the first power line and one end of the second power line are both connected to the same corresponding pixel unit, and the other end of the first power line and the other end of the second power line are both connected to the signal source circuit.

Optionally, several third power lines and several data signal lines are disposed in the display area, any two adjacent third power lines are parallel, any two adjacent data signal lines are parallel, any one of the third power lines and any one of the data signal lines are parallel, one end of each of the third power lines is connected to each corresponding pixel unit, and the other end of each of the third power lines is connected to the signal source circuit.

Optionally, there are one first compensation line and one second compensation line.

One end of the first compensation line is connected to a power line corresponding to a pixel unit farthest from the signal source circuit, one end of the second compensation line is connected to a power line corresponding to a pixel unit farthest from the signal source circuit, and the other end of the first compensation line and the other end of the second compensation line are both connected to the signal source circuit.

Optionally, the first compensation lines and the second compensation lines each transmit an anode voltage used for compensating for each corresponding pixel unit.

Optionally, the first compensation lines and the second compensation lines each transmit a cathode voltage used for compensating for each corresponding pixel unit.

Optionally, fourth power lines and fifth power lines are disposed in the display area, the fourth power lines and the fifth power lines each are configured to transmit the cathode voltage, the fourth power lines are disposed in an area closest to the non-display area in the first display area, each pixel unit in the first display area is connected to the fourth power line, one end of each of the first compensation lines is connected to a fourth power line corresponding to a corresponding pixel unit in the first display area, the fifth power lines are disposed in an area closest to the non-display area in the second display area, each pixel unit in the second display area is connected to the fifth power line, and one end of each of the second compensation lines is connected to a fifth power line corresponding to a corresponding pixel unit in the second display area.

Optionally, each of the pixel units includes:

an organic light-emitting diode, including a cathode;

a thin-film transistor, connected to the cathode and configured to drive the organic light-emitting diode based on the preset driving voltage; and

a compensation structure, connected to the thin-film transistor and configured to use the thin-film transistor to detect a cathode voltage of the organic light-emitting diode and transmit the compensation voltage.

Optionally, the thin-film transistor includes:

a substrate, including a deposition surface; and

a first metal layer, stacked on the deposition surface and connected to the cathode.

The compensation structure includes:

a second metal layer, stacked on the deposition surface and connected to the first metal layer; and

a first insulating layer, stacked on the deposition surface and located between the first metal layer and the second metal layer.

Optionally, the thin-film transistor further includes a transparent glass layer, and the transparent glass layer is stacked between the first metal layer and the cathode.

To solve the technical problem, the embodiments of the present disclosure provide the following technical solutions.

A display device includes the display screen.

Compared with the prior art, in the display screen provided by the embodiments of the present disclosure, the display panel includes the display area and the non-display area. The display area includes several pixel units. The compensation line assembly is disposed in the non-display area and separately connected to each of the pixel units. The signal source circuit is disposed on one side of the display panel and configured to provide the preset driving voltage for each of the pixel units. The compensation circuit is connected to the compensation line assembly and configured to detect the real-time driving voltage of each of the pixel units, determine the to-be-compensated pixel unit based on the preset driving voltage and the real-time driving voltage, and provide the compensation voltage for the to-be-compensated pixel unit. Therefore, by providing a compensation voltage for a to-be-compensated pixel unit, pixel units located in different display areas are driven by the same driving voltage, such that brightness of the different display areas can be uniform, and brightness consistency of the display areas can be further improved.

### BRIEF DESCRIPTION OF DRAWINGS

To describe the technical solutions in the embodiments of the present disclosure more clearly, the following briefly describes the accompanying drawings required for describing the embodiments of the present disclosure. Apparently, the accompanying drawings in the following description show merely some embodiments of the present disclosure, and a person of ordinary skill in the art may still derive other drawings from these accompanying drawings without creative efforts.

FIG. 1 is a schematic structural diagram illustrating a display screen according to an embodiment of the present disclosure;

FIG. 2 is a schematic structural diagram illustrating a drive circuit according to an embodiment of the present disclosure;

FIG. 3 is a schematic diagram illustrating an output characteristic of a typical thin-film transistor;

FIG. 4a is a schematic structural diagram illustrating a display screen according to another embodiment of the present disclosure;

FIG. 4b is a schematic diagram illustrating brightness of a display area after compensation according to an embodiment of the present disclosure;

FIG. 4c is a schematic structural diagram illustrating a display screen according to still another embodiment of the present disclosure;

FIG. 5a is a schematic structural diagram illustrating a display screen according to yet another embodiment of the present disclosure; and

FIG. 5b is a sectional view illustrating a pixel unit according to an embodiment of the present disclosure.

### DESCRIPTION OF EMBODIMENTS

For ease of understanding of the present disclosure, the following describes the present disclosure in more detail with reference to the accompanying drawings and specific embodiments. It should be noted that when one element is, as stated, “fixed to” another element, it may be directly on the another element, or there may be one or more other elements in between. When one element is, as stated, “connected to” another element, it may be directly connected to the another element, or there may be one or more other elements in between. The terms “vertical”, “horizontal”, “left”, “right”, “inner”, “outer” and other similar expressions as used in this specification are just for illustration and only express actual positional relationship. For example, if a certain positional relationship is not strictly vertical for a certain purpose, “vertical” substantially means vertical or uses a vertical characteristic, and then it belongs to the scope of “vertical” in this specification.

Unless otherwise defined, all technical and scientific terms used in this specification have the same meanings as those usually understood by a person skilled in the art of the present disclosure. The terms used in the specification of the present disclosure are just for describing the specific embodiments and are not intended to limit the present disclosure. The term “and/or” used in this specification includes any or all combinations of one or more relevant listed items.

In addition, the technical features involved in different embodiments of the present disclosure as described below may be combined provided that they do not conflict.

An embodiment of the present disclosure provides a display screen.

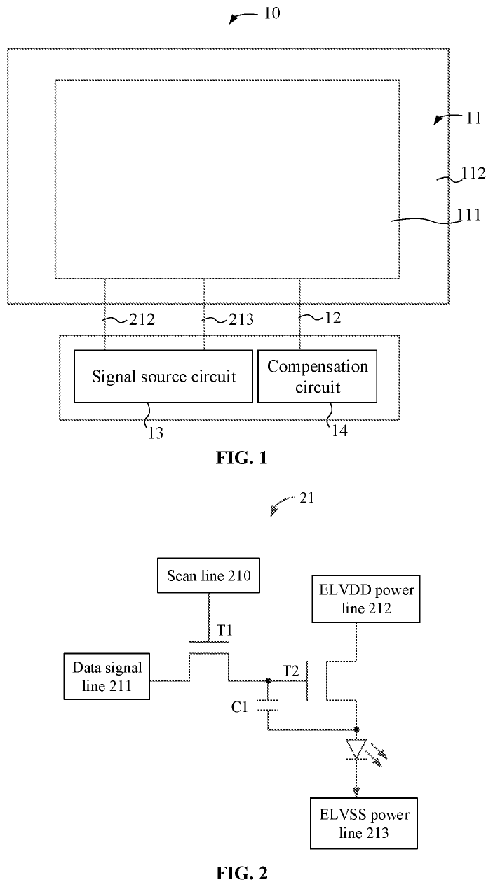

With reference to FIG. 1, a display screen 10 includes: a display panel 11, a compensation line assembly 12, a signal source circuit 13 and a compensation circuit 14.

Optionally, the display panel 11 can use a flexible substrate or a rigid substrate. The flexible substrate includes a flexible material such as a thin glass, metal foil or plastic substrate. For example, the plastic substrate includes flexible structures coated on two sides of a base film. The base film includes resin such as polyimides (PI), polycarbonates (PC), polyethylene terephthalate (PET), polyether sulfone (PES), a polyethylene film (PEN) and fiber reinforced plastic (FRP). The rigid substrate may be, but is not limited to, a glass substrate, a metal substrate, or a ceramic substrate.

The display panel 11 includes a display area 111 and a non-display area 112. The display area 111 includes several pixel units. The pixel unit is driven by a driving voltage to emit light. The pixel unit may be an organic light emitting diode (OLED) light-emitting unit. The pixel unit 111 may sequentially include an anode, a hole injection layer, a hole transport layer, an organic light-emitting layer, an electron transport layer, an electron injection layer and a cathode.

Each pixel unit is connected to a data signal line, a scan line and a power line. With reference to FIG. 2, the pixel unit is driven by a drive circuit 21 to emit light. The drive circuit 21 includes a first thin-film transistor T1, a second thin-film transistor T2 and a storage capacitor C1, where a gate of the first thin-film transistor T1 is configured to connect a scan line 210, the scan line 210 is configured to transmit a scan signal, a drain of the first thin-film transistor T1 is configured to connect a data signal line 211, the data signal line 211 is configured to transmit a data signal, a drain of the second thin-film transistor T2 is configured to connect an ELVDD power line 212, the ELVDD power line 212 is configured to transmit an ELVDD voltage, a source of the second thin-film transistor T2 is configured to connect an ELVSS power line 213, and the ELVSS power line 213 is configured to transmit an ELVSS voltage.

When the scan signal is in a high level, the first thin-film transistor T1 is opened, the data signal charges the storage capacitor C1, a voltage of the storage capacitor C1 controls a current at the drain of the second thin-film transistor T2. When the scan signal is in a low level, the first thin-film transistor T1 is cut off, an electric charge stored in the storage capacitor C1 keeps the second thin-film transistor T2 opening, and thus the current at the drain drives an OLED device to emit light.

In some embodiments, the ELVDD voltage may serve as an anode voltage of the OLED device, the ELVSS voltage may serve as a cathode voltage of the OLED device, and the anode voltage and the cathode voltage are both used for driving the OLED device to emit light, where a difference between the anode voltage and the cathode voltage is a driving voltage.

A lead for connecting the display area 111 to an external circuit is disposed in the non-display area 112. When the display panel 11 is a flexible display panel, a folding axis located at a preset position may be defined in advance on the flexible display panel. To prevent the lead from breakage during folding, a lead area may be folded around the folding axis to form a folding area. In some embodiments, the lead intersects with the folding axis and linearly crosses the folding area, and the lead area may be folded around the folding axis to a back side of the display area 111, so as to reduce a bezel of the display panel 11 and increase a proportion of the display area 111 in the display panel 11. Moreover, because the lead linearly crosses the folding area, lateral stress applied to the lead when the lead is bent around the folding axis can be reduced, and a failure probability of the lead in a folded state can be reduced.

The compensation line assembly 12 is disposed on either side of the non-display area 112, and the compensation line assembly 12 is respectively connected to each pixel unit. For example, the pixel units in the display area 111 are sequentially arranged to form several rows of pixel units, and the compensation line assembly 12 is sequentially connected to each row of the pixel units. The compensation line assembly 12 and the power line serve as two carriers for transmitting different voltages, and the compensation line assembly 12 may separately transmit a compensation voltage, which is different from a related technology that transmits a compensation voltage through a power line. With a structure in which a compensation assembly is additionally used to transmit a compensation voltage, there is no need to use the same power line to transmit a compensation voltage through time division multiplexing. In contrast, a to-be-compensated pixel unit can be synchronously detected, so as to rapidly provide a compensation voltage for the to-be-compensated pixel unit.

The signal source circuit 13 is disposed on one side of the display panel 11. For example, in some embodiments, one side of the display panel 11 is connected to a flexible printed circuit (FPC), and the signal source circuit 13 is bonded to the FPC through a chip on flex (COF) structure.

The signal source circuit 13 serves as a driving source and can provide a driving voltage for each pixel unit. When a specific pixel unit is selected, the specific pixel unit is driven by the driving voltage to emit light. For displaying different frames of images, the signal source circuit 13 may output the same driving voltage or different driving voltages. However, before being applied to an ELVDD power line 212 or an ELVSS power line 213 by the signal source circuit 13, each driving voltage is preset by the signal source circuit 13 based on preset display logic, such that the signal source circuit 13 can provide a preset driving voltage for each pixel unit. Further, for displaying different frames of images, the preset driving voltage may be different or the same.

The compensation circuit 14 is connected to the compensation line assembly 12, and the compensation circuit 14 detects a real-time driving voltage of each pixel unit through the compensation line assembly 12.

Generally, because the OLED device is a current injection type light-emitting display device, under the action of a driving voltage, an organic material and a light-emitting material emit light when carriers are injected and recombined. Therefore, a difference between the ELVDD voltage and the ELVSS voltage is a major factor that affects a light-emitting intensity of the OLED device.

Generally, an IR-drop of the display panel 11 is mainly divided into an in-plane wiring IR-drop and an out-of-plane wiring IR-drop. The IR-drop refers to a voltage drop or rise happening to a power source and a ground network in an integrated circuit. The IR-drop greatly affects a driving capacity of the display panel 11. As brightness of the screen increases, the impact of the IR-drop on the display panel 11 becomes severer. To avoid such impact, generally a sufficient voltage margin may be reserved to ensure that a driving voltage can drive a far end of a flexible screen to emit light. Therefore, brightness of the far end of the screen is greater than that of a near end.

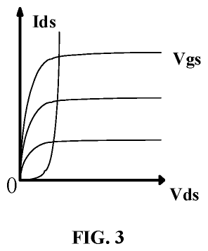

With reference to FIG. 3, under the impact of the IR-drop, a driving voltage in the drive circuit 21 drops, and a gate-source voltage V_{gs} or a drain-source voltage V_{ds} of the second thin-film transistor T2 drops, resulting in a drop of a drain-source current I_{ds}. When the drain-source current I_{ds} drops, the light-emitting brightness of the OLED device decreases accordingly.

In this embodiment, the real-time driving voltage is a voltage which is transmitted to the pixel unit through the power line by the preset driving voltage. The compensation circuit 14 determines the to-be-compensated pixel unit based on the preset driving voltage and the real-time driving voltage, and provides a compensation voltage for the to-be-compensated pixel unit. For example, the ELVSS power line 213 is grounded, and the signal source circuit 13 applies a 5V ELVDD voltage to the ELVDD power line 212, i.e., the 5V ELVDD voltage serves as the preset driving voltage. The ELVDD voltage is transmitted to each pixel unit through metal interconnect lines. Under the impact of the IR-drop, when the ELVDD voltage is transmitted to the pixel unit relatively far from the signal source circuit 13, a driving voltage of the pixel unit relatively far away, i.e., the real-time driving voltage, becomes 4.5 V. In this case, the compensation circuit 14 detects the real-time driving voltage, i.e., 4.5 V, of the pixel unit relatively far through the compensation line assembly 12. Hence, the compensation circuit 14 determines that the real-time driving voltage 4.5 V is smaller than the preset driving voltage 5 V, i.e., the pixel unit relatively far serves as the to-be-compensated pixel unit.

Finally, the compensation circuit 14 calculates a voltage difference 0.5 V based on the real-time driving voltage and the preset driving voltage, i.e., the voltage difference 0.5 V serves as a compensation voltage. The compensation circuit 14 provides the compensation voltage for the pixel unit relatively far through the compensation line assembly 12.

In some embodiments, considering the IR-drop caused by the compensation line assembly 12, the compensation voltage provided by the compensation circuit 14 may be larger than the voltage difference actually calculated. Therefore, the compensation circuit 14 may further correct the voltage difference actually calculated. For example, the compensation circuit 14 calculates the IR-drop based on a length of the compensation line assembly between the to-be-compensated pixel unit and the signal source circuit 13, adds the IR-drop to the voltage difference actually calculated and uses an addition result as a final compensation voltage, and then transmits the final compensation voltage to the to-be-compensated pixel unit through the compensation line assembly 12.

In some embodiments, the signal source circuit 13 or the compensation circuit 14 may be a power supply chip. Or, the signal source circuit 13 and the compensation circuit 14 are integrated on the same chip, or may be further integrated on a controller. The controller can be a general processor, a digital signal processor (DSP), an application-specific integrated circuit (ASIC), a field programmable gate array (FPGA), a single-chip microcomputer, an Acorn RISC machine (ARM) or other programmable-logic devices, a discrete gate or transistor logic, a discrete hardware component or any combination of these parts. Further, the controller may alternatively be any related processor, controller, microcontroller or state machine. The controller may also be a combination implemented as a computing device, e.g., a combination of a DSP and a microprocessor, a plurality of microprocessors, a combination of one or more microprocessors with a DSP core, or any other such configuration.

In this embodiment, by providing the compensation voltage to the to-be-compensated pixel unit, pixel units located in different display areas are driven by the same driving voltage, such that brightness of the different display areas can be uniform, thereby improving brightness consistency of the display areas.

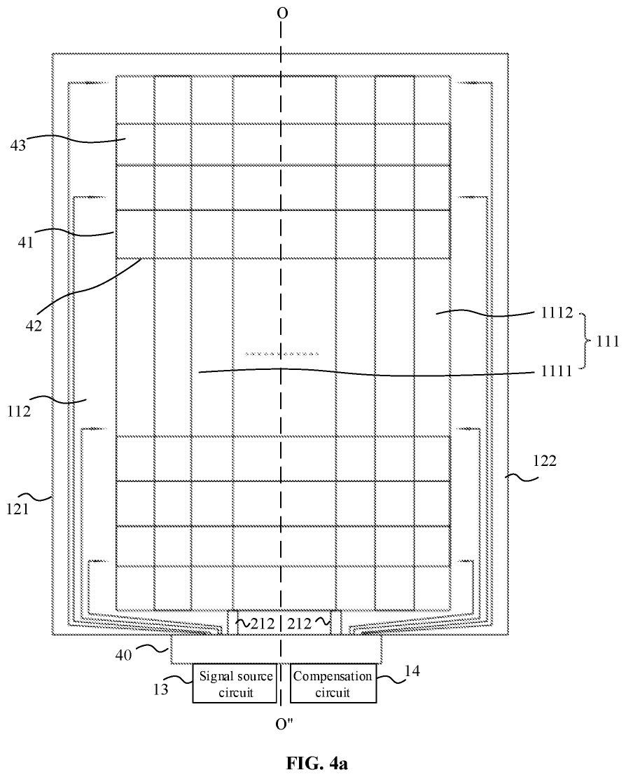

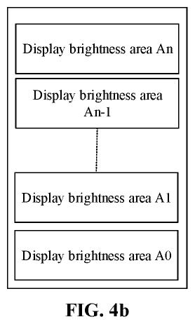

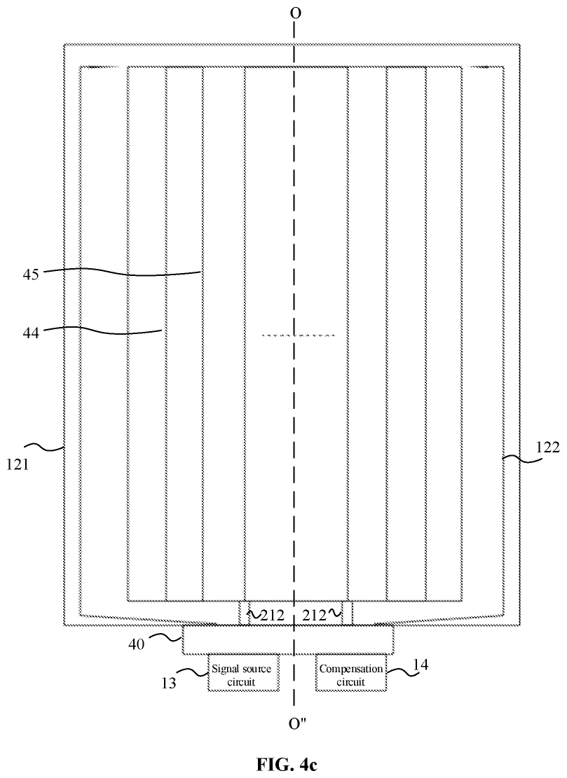

In some embodiments, with reference to FIG. 4a, the compensation line assembly 12 includes several first compensation lines 121. Each of the first compensation lines 121 is disposed on one side of the non-display area 112, where one end of each of the first compensation lines 121 is connected to a corresponding pixel unit, and the other end of each of the first compensation lines 121 is connected to the compensation circuit 14. In some embodiments, the compensation circuit 14 is connected to one side of a binding area 40, and the other end of each of the first compensation lines 121 is connected to the compensation circuit 14 across the binding area 40. The signal source circuit 13 is also connected to one side of the binding area 40.

During operation, the signal source circuit 13 transmits the preset driving voltage to each pixel unit through the ELVSS power line 213 and/or the ELVDD power line 212 to light up each pixel unit, and the compensation circuit 14 transmits the compensation voltage to a corresponding pixel unit through a corresponding first compensation line 121, such that the brightness of the display area is uniform.

In some embodiments, the brightness of the display area can be uniform by only disposing several first compensation lines 121. In some embodiments, to improve compensation reliability, the compensation voltage can be provided in a double-sided compensation mode.

Still with reference to FIG. 4a, the display area 111 includes a first display area 1111 and a second display area 1112. The first display area 1111 and the second display area 1112 are symmetrical, e.g., the first display area 1111 and the second display area 1112 are symmetrical about a central axis OO″ of the display area 111.

The compensation line assembly 12 further includes several second compensation lines 122. The second compensation lines 122 are disposed on the other side of the non-display area 112.

One end of each of the first compensation lines 121 is connected to a corresponding pixel unit in the first display area 1111, and the other end of each of the first compensation lines 121 is connected to the compensation circuit 14.

One end of each of the second compensation lines 122 is connected to a corresponding pixel unit in the second display area 1112, the other end of each of the second compensation lines 122 is connected to the compensation circuit 14, and the first compensation lines 121 and the second compensation lines 122 connected to the same row of pixel units are symmetrical about the central axis OO″ of the display area 111.

During operation, the signal source circuit 13 transmits the preset driving voltage to each pixel unit through the ELVSS power line 213 and/or the ELVDD power line 212 to light up each pixel unit, and the compensation circuit 14 transmits the compensation voltage to a corresponding pixel unit in the first display area 1111 through a corresponding first compensation line 121, and transmits the compensation voltage to a corresponding pixel unit in the second display area 1112 through a corresponding second compensation line 122, such that the brightness of the display area is uniform.

Due to symmetry, lengths of the first compensation lines 121 and the second compensation lines 122 connected to the same row of pixel units are the same, and the IR-drop and other electrical influencing parameters of the first compensation lines 121 and the second compensation lines 122 connected to the same row of pixel units are the same or almost the same. Therefore, when the same row of pixel units are driven, on one hand, the compensation voltage is provided in the double-sided compensation mode, such that an adjustment efficiency of the brightness uniformization can be improved. On the other hand, in a single-sided compensation mode, the several first compensation lines 121 need to be sequentially connected to each pixel unit, which increases the wiring difficulty. In addition, the compensation circuit 14 further needs to calculate IR-drop corresponding to first compensation lines 121 that have different wiring lengths, such that a compensation voltage can be precisely provided. Apparently, this mode increases logical calculation of the compensation circuit 14 and increases the design difficulty. In this embodiment, with the double-sided compensation mode, the first compensation lines 121 only need to be connected to pixel units in the first display area 1111, and the second compensation lines 122 only need to be connected to pixel units in the second display area 1112. Therefore, wiring is easier, a calculation amount is smaller, and the design difficulty is lower.

In some embodiments, the first compensation lines 121 and the second compensation lines 122 each transmit an anode voltage used for compensating for each corresponding pixel unit, i.e., the compensation circuit 14 can compensate for an ELVDD voltage through the first compensation lines 121 and the second compensation lines 122.

In some other embodiments, the first compensation lines 121 and the second compensation lines 122 each transmit a cathode voltage used for compensating for each corresponding pixel unit, i.e., the compensation circuit 14 can compensate for an ELVSS voltage through the first compensation lines 121 and the second compensation lines 122.

In some embodiments, still with reference to FIG. 4a, several first power lines 41 and several second power lines 42 are disposed in the display area 111, where any two adjacent first power lines 41 are parallel, any two adjacent second power lines 42 are parallel, and any one of the first power lines 41 is perpendicular to any one of the second power lines 42. Therefore, boundary lines of any two adjacent first power lines 41 and any two adjacent second power lines 42 define a pixel area 43, and each pixel area 43 may be provided with one or more pixel units.

One end of the first power line 41 and one end of the second power line 42 are both connected to the same corresponding pixel unit, and the other end of the first power line 41 and the other end of the second power line 42 are both connected to the signal source circuit 13. For example, one end of the first power line 41 communicates with one end of the second power line 42, and the other end of the first power line 41 communicates with the other end of the second power line 42. The preset driving voltage may be transmitted to the second power line 42 through the first power line 41, or may be transmitted to the first power line 41 through the second power line 42.

One end of each of the first compensation lines 121 may be connected to one or more pixel units in each pixel area 43 in the first display area 1111. Or, a line of the first power lines 41 or the second power lines 42 may be multiplexed for connection to one or more pixel units in each pixel area 43 in the first display area 1111.

One end of each of the second compensation lines 122 may be connected to one or more pixel units in each pixel area 43 in the second display area 1112. Or, a line of the first power lines 41 or the second power lines 42 may be multiplexed for connection to one or more pixel units in each pixel area 43 in the second display area 1112.

With reference to FIG. 4b, the display area 111 includes n+1 display brightness areas, e.g., A0 to An. Before compensation, brightness is ranked in the following order: A0>A1>A2 . . . >An−1>An. After each display brightness area is compensated for through the first compensation lines 121 or the second compensation lines 122, brightness is ranked in the following order: A0=A1=A2 . . . =An−1=An.

Therefore, when the first power lines 41 and the second power lines 42 are laid out on the display screen in a cross manner and the compensation circuit 14 determines pixel units in a specific pixel area as to-be-compensated pixel units, the compensation circuit 14 provides compensation voltages through the first compensation lines 121 or the second compensation lines 122. Therefore, in this mode, a compensation voltage can be provided for to-be-compensated pixel units located at different positions dynamically in multiple areas, such that the brightness of the display area is uniform.

In some embodiments, considering that different display screens adopt different power line wiring modes, connection modes of compensation lines are also different. Therefore, different from the above embodiments, with reference to FIG. 4c, several third power lines 44 and several data signal lines 45 are disposed in the display area 111, any two adjacent third power lines 44 are parallel, any two adjacent data signal lines 45 are parallel, any one of the third power lines 44 and any one of the data signal lines 45 are parallel, one end of each of the third power lines 44 is connected to a corresponding pixel unit, and the other end of each of the third power lines 44 is connected to the signal source circuit 13.

Generally, during fabricating of a thin-film transistor substrate and wiring, considering a limitation on the number of masks, the third power lines 44 and the data signal lines 45 are made from the same layer of metal. In some embodiments, because the first compensation lines or the second compensation lines 122 cannot cross lines of the data signal lines 45, one end of the first compensation line 121 transmits a compensation voltage by multiplexing a line of the third power lines 44. One end of the second compensation line 122 transmits a compensation voltage by multiplexing a line of the third power lines 44.

When the power lines and the data signal lines share the same layer of metal for wiring on the display screen, i.e., the third power lines 44 and the data signal lines 45 are parallel, during operation, the signal source circuit 13 provides the preset driving voltage through the third power lines 44, and the compensation circuit transmits the compensation voltage through the first compensation lines 121 or the second compensation lines 122, thereby relieving non-uniform brightness of the display screen and realizing dynamic bottom compensation of the display screen.

In some embodiments, still with reference to FIG. 4c, there are one first compensation line 121 and one second compensation line 122. One end of the first compensation line 121 is connected to a power line corresponding to a pixel unit farthest from the signal source circuit 13, one end of the second compensation line 122 is connected to a power line corresponding to a pixel unit farthest from the signal source circuit, and the other end of the first compensation line 121 and the other end of the second compensation line 122 are both connected to the signal source circuit 13. The corresponding power line may be an ELVDD power line 212.

When the power lines and the data signal lines share the same layer of metal for wiring on the display screen, the first compensation lines 121 and the second compensation lines 122 are respectively connected to power lines corresponding to pixel units farthest from the signal source circuit, such that the impact of the IR-drop can be minimized, it is ensured that the brightness of the display area is effectively compensated for, and the brightness of the display area is uniform.

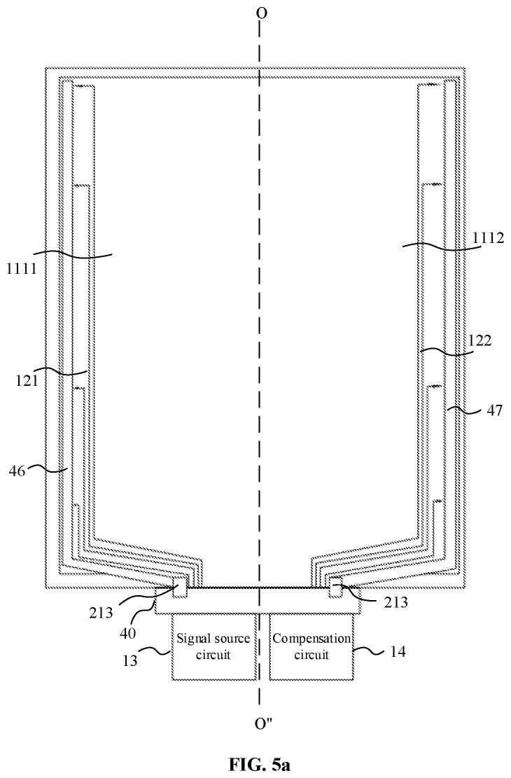

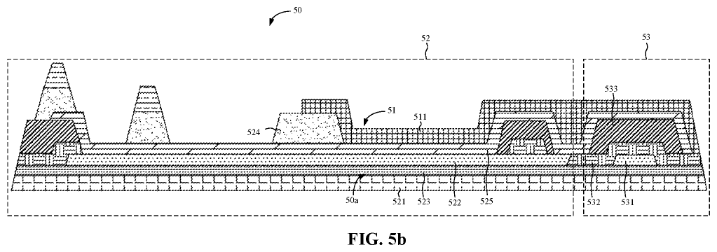

In some embodiments, in addition to an ELVDD voltage, an ELVSS voltage can be compensated for. Therefore, different from the above embodiments, with reference to FIG. 5a, fourth power lines 46 and fifth power lines 47 are disposed in the display area 111, and the fourth power lines 46 and the fifth power lines 47 each are configured to transmit a cathode voltage, i.e., the fourth power lines 46 and the fifth power lines 47 each are an ELVSS power line 213.

The fourth power lines 46 are disposed in an area closest to the non-display area 112 in the first display area 1111, each pixel unit in the first display area 1111 is connected to the fourth power line 46, and one end of each of the first compensation lines 121 is connected to a fourth power line 46 corresponding to a corresponding pixel unit in the first display area 1111. The fifth power lines 47 are disposed in an area closest to the non-display area 112 in the second display area 1112, each pixel unit in the second display area 1112 is connected to the fifth power line 47, and one end of each of the second compensation lines 122 is connected to a fifth power line 47 corresponding to a corresponding pixel unit in the second display area 1112.

During operation, the first compensation line 121 transmits an ELVSS compensation voltage to a fourth power line 46 corresponding to a to-be-compensated pixel unit, or the second compensation line 122 transmits an ELVSS compensation voltage to a fifth power line 47 corresponding to a to-be-compensated pixel unit, thereby relieving the non-uniform brightness of the display area 111.

In some embodiments, with reference to FIG. 5b, each pixel unit 50 includes: an organic light-emitting diode 51, a thin-film transistor 52 and a compensation structure 53.

The organic light-emitting diode 51 includes a cathode 511. The thin-film transistor 52 is connected to the cathode 511. The compensation structure 53 is connected to the thin-film transistor 52.

The thin-film transistor 52 is configured to drive the organic light-emitting diode 51 based on the preset driving voltage. The compensation structure 53 is configured to detect a cathode voltage of the organic light-emitting diode 51 and transmit the compensation voltage through the thin-film transistor 52. For example, when the thin-film transistor 52 is selected and opened, the compensation structure 53 can detect the cathode voltage of the organic light-emitting diode 51 and transmit the compensation voltage.

Still with reference to FIG. 5b, the thin-film transistor 52 includes a substrate 521 and a first metal layer 522. The substrate 521 includes a deposition surface 50a. The first metal layer 522 is stacked on the deposition surface 50a and connected to the cathode 511.

In some embodiments, the substrate 521 adopts a flexible substrate or other material structures. Still with reference to FIG. 5b, in some embodiments, a buffer layer 523 is stacked on the deposition surface of the substrate 521. The buffer layer 523 can protect the substrate 521 and improve electrical performance of the thin-film transistor 52.

In some embodiments, the buffer layer 523 is made of inorganic matter.

The compensation structure 53 includes a second metal layer 531 and a first insulating layer 532. The second metal layer 531 is stacked on the deposition surface 50a. In addition, the second metal layer 531 is connected to the first metal layer 522 and the compensation line assembly 12. The first insulating layer 532 is stacked on the deposition surface 50a and located between the first metal layer 522 and the second metal layer 531.

During operation, the second metal layer 531 detects a real-time driving voltage of the first metal layer 522 and transmits the real-time driving voltage to the compensation circuit 14 through the compensation line assembly 12. The compensation circuit 14 transmits a compensation voltage to the second metal layer 531 through the compensation line assembly. The second metal layer 531 then applies the compensation voltage to the first metal layer 522.

In some embodiments, the first metal layer 522 or the second metal layer 531 serves as source metal or drain metal. The first metal layer 522 or the second metal layer 531 may be made of Mo or AI or other metal oxides.

In some embodiments, the first insulating layer 532 adopts a single-layer silicon dioxide (SiO₂) or double-layer silicon dioxide/silicon nitride (SiO₂/SiNx) structure.

To realize bottom light emission, in some embodiments, still with reference to FIG. 5b, the thin-film transistor 52 further includes a transparent glass layer 525. The transparent glass layer 525 is stacked between the first metal layer 522 and the cathode 511. Light can penetrate through the transparent glass layer 525 to emit.

The transparent glass layer 525 includes indium tin oxide (ITO), indium zinc oxide (IZO), zinc oxide (ZnO), indium tin zinc oxide (ITZO), etc.

In some embodiments, still with reference to FIG. 5b, the thin-film transistor 52 further includes a pixel defining unit 524, where the pixel defining unit 524 is stacked on the transparent glass layer 525 and is far from the first metal layer 522.

In some embodiments, still with reference to FIG. 5b, the first insulating layer 532 surrounds the second metal layer 531. In addition, the compensation structure 53 further includes an organic film layer 533. The organic film layer 533 is stacked on the first insulating layer 532 and is far from the second metal layer 531. In addition, the transparent glass layer 525 envelops the organic film layer 533. The organic film layer 533 may be insulating and improve electrical performance of the thin-film transistor 52.

It can be understood that the terms such as “stacked”, “formed”, “applied” or “disposed” are used to express the positional relationship between layers of one or more interlayer materials involved in the embodiments of the present disclosure illustrated herein. A person skilled in the art can understand that any terms such as “stacked”, “formed” or “applied” can cover all modes, types and techniques of “stacked”, for example, sputtering, electroplating, molding, chemical vapor deposition (CVD), physical vapor deposition (PVD), vaporization, hybrid physical-chemical vapor deposition (HPCVD), plasma enhanced chemical vapor deposition (PECVD), low pressure chemical vapor deposition (LPCVD), etc.

As another aspect of the present disclosure, an embodiment of the present disclosure provides a display device. In this embodiment, the display screen described in the above embodiments may be selected for the display device.

Therefore, by providing a compensation voltage for a to-be-compensated pixel unit, pixel units located in different display areas are driven by the same driving voltage, such that brightness of the different display areas can be uniform, and brightness consistency of the display areas can be further improved.

Finally, it should be noted that the above embodiments are merely used to describe the technical solutions of the present disclosure, but not intended to limit the present disclosure. The above embodiments or technical features in different embodiments may also be combined under the idea of the present disclosure, the steps may be carried out in any order, and there may be many other variations of the different aspects of the present disclosure described above, which are not provided in detail for brevity. Although the present disclosure is described in detail with reference to the preceding embodiments, it should be understood that a person of ordinary skill in the art may still make modifications to the technical solutions described in the preceding embodiments or make equivalent replacements to some technical features. Such modifications or replacements do not make the essence of the corresponding technical solutions depart from the scope of the technical solutions in the embodiments of the present disclosure.

What is claimed is:

1. A display screen, comprising:
a display panel, comprising a display area and a non-display area, wherein the display area comprises several pixel units;
a compensation line assembly, disposed in the non-display area, wherein the compensation line assembly is connected to each of the pixel units;
a signal source circuit, disposed on one side of the display panel and operable to provide a preset driving voltage for each of the pixel units; and
a compensation circuit, connected to the compensation line assembly and operable to detect a real-time driving voltage of each of the pixel units, determine a to-be-compensated pixel unit based on the preset driving voltage and the real-time driving voltage, and provide a compensation voltage for the to-be-compensated pixel unit.

2. The display screen according to claim 1, wherein the compensation line assembly comprises:
several first compensation lines, disposed on one side of the non-display area, wherein one end of each of the first compensation lines is connected to a corresponding pixel unit, and the other end of each of the first compensation lines is connected to the compensation circuit.

3. The display screen according to claim 2, wherein
the display area comprises a first display area and a second display area, the first display area and the second display area are symmetrical, and one end of each of the first compensation lines is connected to a corresponding pixel unit in the first display area; and
The compensation line assembly further comprises several second compensation lines, each of the second compensation lines is disposed on the other side of the non-display area, one end of each of the second compensation lines is connected to a corresponding pixel unit in the second display area, the other end of each of the second compensation lines is connected to the compensation circuit, and first compensation lines and second compensation lines that are connected to the same row of pixel units are symmetrical about a central axis of the display area.

4. The display screen according to claim 3, wherein several first power lines and several second power lines are disposed in the display area, any two adjacent first power lines are parallel, any two adjacent second power lines are parallel, any one of the first power lines is perpendicular to any one of the second power lines, one end of the first power line and one end of the second power line are both connected to a same corresponding pixel unit, and the other end of the first power line and the other end of the second power line are both connected to the signal source circuit.

5. The display screen according to claim 3, wherein several third power lines and several data signal lines are disposed in the display area, any two adjacent third power lines are parallel, any two adjacent data signal lines are parallel, any one of the third power lines and any one of the data signal lines are parallel, one end of each of the third power lines is connected to a corresponding pixel unit, and the other end of each of the third power lines is connected to the signal source circuit.

6. The display screen according to claim 5, wherein
one end of the first compensation line is connected to a power line corresponding to a pixel unit farthest from the signal source circuit, one end of the second compensation line is connected to a power line corresponding to a pixel unit farthest from the signal source circuit, and the other end of the first compensation line and the other end of the second compensation line are both connected to the signal source circuit.

7. The display screen according to claim 3, wherein
the first compensation lines and the second compensation lines each transmit an anode voltage compensating for each corresponding pixel unit.

8. The display screen according to claim 4, wherein
the first compensation lines and the second compensation lines each transmit an anode voltage compensating for each corresponding pixel unit.

9. The display screen according to claim 5, wherein
the first compensation lines and the second compensation lines each transmit an anode voltage compensating for each corresponding pixel unit.

10. The display screen according to claim 6, wherein
the first compensation lines and the second compensation lines each transmit an anode voltage compensating for each corresponding pixel unit.

11. The display screen according to claim 3, wherein
the first compensation lines and the second compensation lines each transmit a cathode voltage compensating for each corresponding pixel unit.

12. The display screen according to claim 4, wherein
the first compensation lines and the second compensation lines each transmit a cathode voltage compensating for each corresponding pixel unit.

13. The display screen according to claim 5, wherein
the first compensation lines and the second compensation lines each transmit a cathode voltage compensating for each corresponding pixel unit.

14. The display screen according to claim 6, wherein
the first compensation lines and the second compensation lines each transmit a cathode voltage compensating for each corresponding pixel unit.

15. The display screen according to claim 11, wherein fourth power lines and fifth power lines are disposed in the display area, the fourth power lines and the fifth power lines each are operable to transmit the cathode voltage, the fourth power lines are disposed in an area closest to the non-display area in the first display area, each pixel unit in the first display area is connected to the fourth power line, one end of each of the first compensation lines is connected to a fourth power line corresponding to a corresponding pixel unit in the first display area, the fifth power lines are disposed in an area closest to the non-display area in the second display area, each pixel unit in the second display area is connected to the fifth power line, and one end of each of the second compensation lines is connected to a fifth power line corresponding to a corresponding pixel unit in the second display area.

16. The display screen according to claim 11, wherein each of the pixel units comprises:
an organic light-emitting diode, comprising a cathode;
a thin-film transistor, connected to the cathode and operable to drive the organic light-emitting diode based on the preset driving voltage; and
a compensation structure, connected to the thin-film transistor and operable to through the thin-film transistor detect a cathode voltage of the organic light-emitting diode and transmit the compensation voltage.

17. The display screen according to claim 16, wherein
the thin-film transistor comprises:
a substrate, comprising a deposition surface; and
a first metal layer, stacked on the deposition surface and connected to the cathode;
the compensation structure comprises:
a second metal layer, stacked on the deposition surface and connected to the first metal layer and the compensation line assembly; and
a first insulating layer, stacked on the deposition surface and located between the first metal layer and the second metal layer.

18. The display screen according to claim 17, wherein the thin-film transistor further comprises a transparent glass layer, and the transparent glass layer is stacked between the first metal layer and the cathode.

19. A display device, comprising a display screen, the display screen comprising:
a display panel, comprising a display area and a non-display area, wherein the display area comprises several pixel units;
a compensation line assembly, disposed in the non-display area, wherein the compensation line assembly is connected to each of the pixel units;
a signal source circuit, disposed on one side of the display panel and operable to provide a preset driving voltage for each of the pixel units; and
a compensation circuit, connected to the compensation line assembly and operable to detect a real-time driving voltage of each of the pixel units, determine a to-be-compensated pixel unit based on the preset driving voltage and the real-time driving voltage, and provide a compensation voltage for the to-be-compensated pixel unit.
